(19) United States
(12) Patent Application Publication
(10) Pub. No.: US 2026/0191009 A1
(43) Pub. Date: Jul. 2, 2026

(54) SEMICONDUCTOR PACKAGE

(71) Applicant: Samsung Electronics Co., Ltd., Suwon-si (KR)

(72) Inventors: Buwon KIM, Suwon-si (KR); Heewoo AN, Suwon-si (KR)

(73) Assignee: Samsung Electronics Co., Ltd., Suwon-si (KR)

(21) Appl. No.: 19/317,685

(22) Filed: Sep. 3, 2025

(30) Foreign Application Priority Data
Dec. 30, 2024 (KR) 10-2024-0201172

(51) Int. Cl. H01L 23/552; H01L 23/00; H01L 23/498; H01L 25/065; H01L 25/18; H10B 80/00

(52) U.S. Cl. CPC H10W 42/20; H10W 70/65; H10W 90/00; H10B 80/00; H10W 42/271; H10W 72/642; H10W 72/647; H10W 72/834; H10W 90/20; H10W 90/24; H10W 90/762; H10W 90/764

(57) ABSTRACT

Example embodiments are directed to a semiconductor package having a relatively reduced thickness and configured to reduce signal crosstalk between two channels used by the semiconductor package. The semiconductor package includes a package substrate including a first substrate pad and a second substrate pad, at least one first semiconductor chip including first chip pads and on the package substrate, at least one second semiconductor chip including second chip pads and on the first semiconductor chip, a first printed wiring connecting some of the second chip pads and the first chip pads to the first substrate pad, a second printed wiring connecting the other second chip pads to the second substrate pad, an isolation insulating layer insulating the first printed wiring from the second printed wiring in an overlapping region, in which the first printed wiring and the second printed wiring overlap, and a ground layer inside the isolation insulating layer.

### CROSS-REFERENCE TO RELATED APPLICATION

This U.S. non-provisional application claims priority under 35 U.S.C. § 119 to Korean Patent Application No. 10-2024-0201172, filed on Dec. 30, 2024, in the Korean Intellectual Property Office, the disclosure of which is incorporated by reference herein in its entirety.

### BACKGROUND

Example embodiments relate to a semiconductor package including a chip stack structure and/or a method of manufacturing the semiconductor package.

With the rapid development of the electronics industry and user needs, it is desirable for electronic devices to be more compact and lighter. With an increase in the compactness and lightness of electronic devices, it is advantageous for semiconductor packages used in the electronic devices to also be more compact and lighter while having higher performance, higher capacity, and higher reliability. With the higher performance and higher capacity of semiconductor packages, signal transmission paths between semiconductor packages or within a semiconductor package are becoming more complex. Accordingly, it is beneficial to design and manufacture a semiconductor package that satisfies the size and/or performance criteria and reliably transmits signals. The thickness of a semiconductor package may be increased to realize the higher capacity and higher performance of the semiconductor package. However, increasing the thickness of a semiconductor package may make the electronic devices less compact and less light.

### SUMMARY

Example embodiments are directed to a semiconductor package having a reduced thickness and configured to reduce or minimize signal crosstalk between two channels used by the semiconductor package.

The problems to be solved by the technical idea of the example embodiments are not limited to those mentioned above, and the example embodiments can be clearly understood by those skilled in the art from the description below.

According to some example embodiments, a semiconductor package includes a package substrate including a first substrate pad and a second substrate pad, at least one first semiconductor chip including a plurality of first chip pads and on the package substrate in a stepped structure, at least one second semiconductor chip including a plurality of second chip pads and on the at least one first semiconductor chip in a stepped structure, a first printed wiring connecting a portion of the plurality of second chip pads and the first chip pads to the first substrate pad, a second printed wiring connecting a remaining portion of the plurality of second chip pads to the second substrate pad, an isolation insulating layer isolating the first printed wiring from the second printed wiring and covering a portion of the first printed wiring on the at least one first semiconductor chip, in an overlapping region in which the first printed wiring overlaps the second printed wiring, and a ground layer inside the isolation insulating layer.

According to some example embodiments, a semiconductor package includes a package substrate including a first substrate pad and a second substrate pad, at least one first semiconductor chip including a first signal chip pad and on the package substrate in a stepped structure, at least one second semiconductor chip including a second signal chip pad and on the at least one first semiconductor chip in a stepped structure, a first printed wiring connecting the first signal chip pad to the first substrate pad, a second printed wiring connecting the second signal chip pad to the second substrate pad, a lower isolation insulating layer covering the first printed wiring in an overlapping region, in which the first printed wiring overlaps the second printed wiring, a ground layer covering the lower isolation insulating layer, and an upper isolation insulating layer covering the ground layer and having a portion of the second printed wiring on a top surface of the upper isolation insulating layer.

According to some example embodiments, a semiconductor package includes a package substrate, at least one first semiconductor chip of a first channel and on the package substrate in a stepped structure, at least one second semiconductor chip of a second channel and on the at least one first semiconductor chip in a stepped structure, a first printed wiring contacting a top surface and a side surface of the at least one first semiconductor chip, the first printed wiring providing signal connection of the first channel, a second printed wiring contacting a top surface and a side surface of the at least one second semiconductor chip, the second printed wiring providing signal connection of the second channel, and a multi-isolation layer including a ground layer therein and between the first printed wiring and the second printed wiring in an overlapping region, in which the first printed wiring overlaps the second printed wiring.

According to some example embodiments, a method of manufacturing a semiconductor package includes stacking at least one first semiconductor chip on a package substrate in a stepped structure, the package substrate including a first substrate pad and a second substrate pad, and the at least one first semiconductor chip including a plurality of first chip pads, stacking at least one second semiconductor chip on the at least one first semiconductor chip in a stepped structure, the at least one second semiconductor chip including a plurality of second chip pads, connecting a portion of the plurality of second chip pads and the first chip pads to the first substrate pad using a first printed wiring, connecting a remaining portion the plurality of second chip pads to the second substrate pad using a second printed wiring, and forming an isolation insulating layer to isolate the first printed wiring from the second printed wiring, the isolation insulating layer covering a portion of the first printed wiring on the at least one first semiconductor chip in an overlapping region, and the first printed wiring overlapping the second printed wiring in the overlapping region. According to some example embodiments, the first printed wiring contacts a top surface and a side surface of the at least one first semiconductor chip, and the second printed wiring contacts a top surface and a side surface of the at least one second semiconductor chip and contacts the isolation insulating layer on the at least one first semiconductor chip. According to some example embodiments, the plurality of first chip pads include a first signal chip pad, a first ground chip pad, and a first power chip pad, the plurality of second chip pads include a second signal chip pad, a second ground chip pad, and a second power chip pad, and the second printed wiring connects the second signal chip pad to the second substrate pad. According to some example embodiments, the first substrate pad includes a first signal substrate pad, a first ground substrate pad, and a first power substrate pad, and the first printed wiring includes, a signal wiring connects the first signal chip pad to the first signal substrate pad, a ground wiring connects the first ground chip pad and the second ground chip pad to the first ground substrate pad, and a power wiring connects the first power chip pad and the second power chip pad to the first power substrate pad. According to some example embodiments, the overlapping region includes a region from an exposed top surface of a topmost semiconductor chip of the at least one first semiconductor chip to the first ground substrate pad.

### BRIEF DESCRIPTION OF THE DRAWINGS

Example embodiments will be more clearly understood from the following detailed description taken in conjunction with the accompanying drawings in which:

FIGS. 1A, 1B, and 1C are a schematic perspective view and cross-sectional views of a semiconductor package according to some example embodiments.

FIGS. 2A, 2B, and 2C are a schematic perspective view and cross-sectional views of a semiconductor package according to some example embodiments.

FIGS. 3A, 3B, 3C, and 3D are schematic perspective views of a semiconductor package according to some example embodiments.

FIGS. 4A, 4B, 4C, 4D, and 4E are plan views schematically illustrating a method of manufacturing a semiconductor package, according to some example embodiments.

### DETAILED DESCRIPTION OF THE EMBODIMENTS

Hereinafter, example embodiments will be described in detail with reference to the accompanying drawings. In the drawings, like reference characters denote like elements, and redundant descriptions thereof will be omitted.

In the drawings, the thickness of layers, films, panels, regions, etc., are exaggerated for clarity.

In the drawings, parts having no relationship with the description are omitted for clarity, and the same or similar constituent elements are indicated by the same reference numeral throughout the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

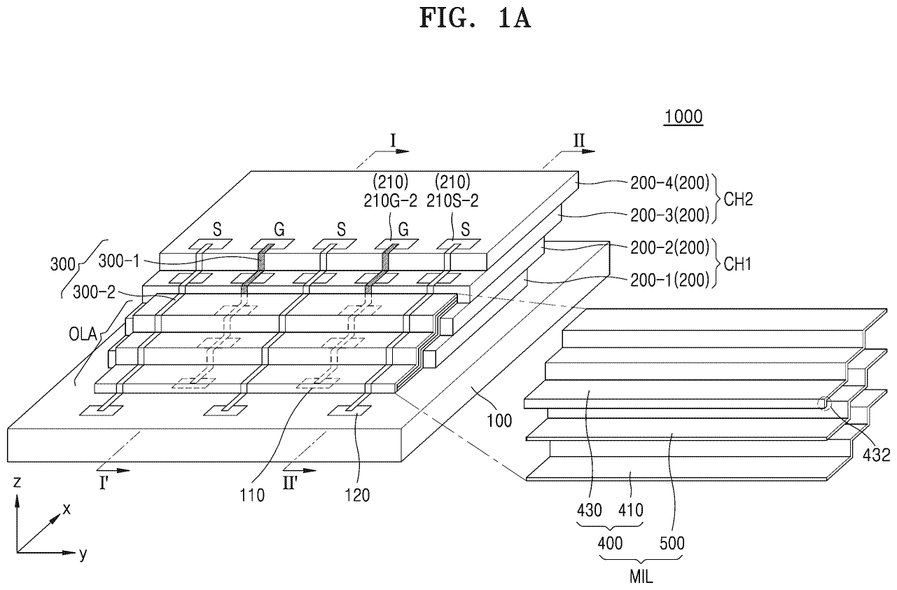

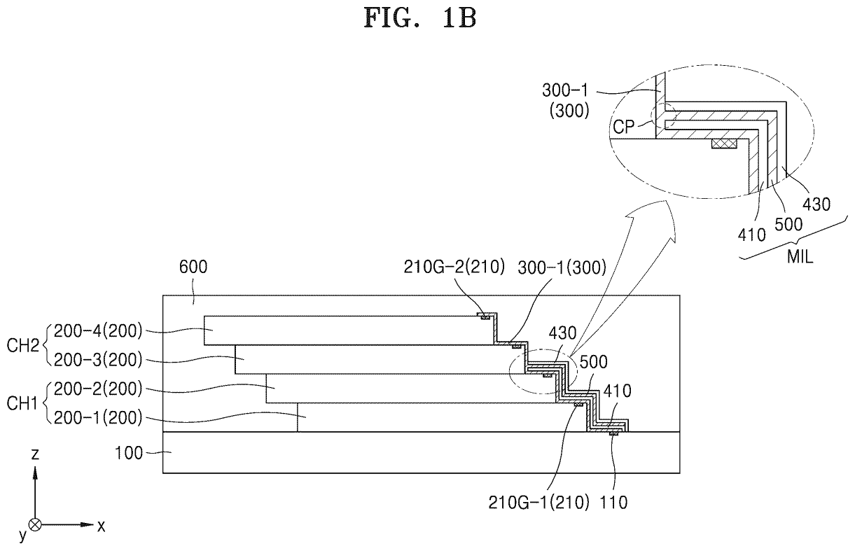

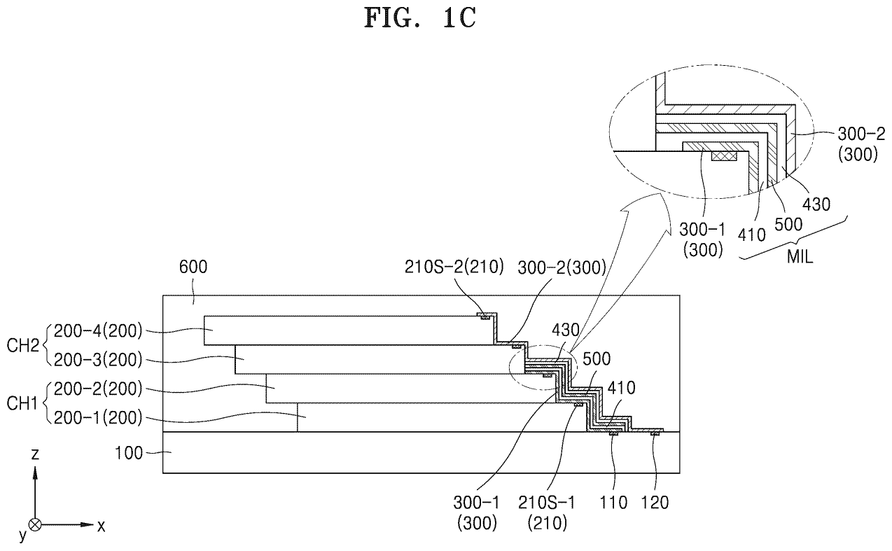

FIGS. 1A to 1C are a schematic perspective view and cross-sectional views of a semiconductor package 1000 according to some example embodiments. FIG. 1B is a cross-sectional view taken along line I-I′ in FIG. 1A. FIG. 1C is a cross-sectional view taken along line II-II′ in FIG. 1A. A sealant 600 is not shown in FIG. 1A for sake of clarity of illustration.

Referring to FIGS. 1A to 1C, a semiconductor package 1000 may include a package substrate 100, semiconductor chips 200 (individually, semiconductor chips 200-1, 200-2, 200-3, and 200-4), a printed wiring 300, a multi-isolation layer MIL, and a sealant 600.

The package substrate 100 may include a substrate body layer and substrate pads (e.g., 110 and 120). The substrate body layer may be composed of various materials. For example, the substrate body layer may be or include silicon, ceramic, an organic material, glass, epoxy resin, or the like according to the type of package substrate. In the semiconductor package 1000, the package substrate 100 may include a printed circuit board (PCB). Therefore, the substrate body layer may include glass epoxy (or flame retardant 4 (FR-4)) resin, phenol resin, or bismaleimide triazine (BT) resin. However, the material of the substrate body layer is not limited to those materials mentioned above.

The substrate body layer may have a single-layer or multi-layer structure. The package substrate 100 may include a single-layer PCB having a wiring on one side thereof and a double-layer PCB having a wiring on each of both sides thereof. In the case of a double-layer PCB, an upper wiring may be electrically connected to a lower wiring through a via contact that passes through the substrate body layer. At least three layers of copper (Cu) foil may be formed in the substrate body layer by using an insulator called prepreg. At least three layers of wiring may be formed in the substrate body layer according to the number of layers of Cu foil.

A substrate protection layer may be formed on the bottom and top surfaces of the substrate body layer. The substrate protection layer may cover and protect wirings on top and bottom surfaces of the substrate body layer. For example, the substrate protection layer may include solder resist (SR). However, the material of the substrate protection layer is not limited to SR. For example, the substrate protection layer may include an insulating layer composed of various materials according to the type or function of substrate body layer. The substrate pads (110 and 120) on the top surface of the substrate body layer may be exposed from the substrate protection layer. The substrate body layer may occupy most of the package substrate 100 and may be substantially the same as the package substrate 100 in appearance. Accordingly, the substrate body layer and the package substrate 100 are referred to interchangeably in this discussion.

The substrate pads (110 and 120) may be on the top surface of the package substrate 100 and may be electrically connected to chip pads 210 of the semiconductor chips 200 through the printed wiring 300. The substrate pads may include a first substrate pad 110 and a second substrate pad 120. The first substrate pad 110 and the second substrate pad 120 may be arranged on the top surface of the package substrate 100 in correspondence to a direction in which a stepped structure is formed. For example, as seen in FIG. 1B, the stepped structure of semiconductor chips 200 may be formed on the right in the x-direction, and the substrate pads (110 and 120) may be arranged on the top surface of the package substrate 100 on the right side of the semiconductor chips 200 in the x-direction.

The first substrate pad 110 may be spaced apart from the semiconductor chips 200 in the x-direction. A plurality of first substrate pads 110 may be arranged in the y-direction. The second substrate pad 120 may also be spaced apart from the semiconductor chips 200 in the x-direction. A plurality of second substrate pads 120 may be arranged in the y-direction. The second substrate pad 120 may be spaced further away from the semiconductor chips 200 in the x-direction than the first substrate pad 110.

The first substrate pad 110 may be connected to a first printed wiring 300-1, and the second substrate pad 120 may be connected to a second printed wiring 300-2. The connection relationship between the substrate pads (110 and 120) and the printed wiring 300 is explained in the description of the printed wiring 300 below.

The semiconductor chips 200 may be mounted on the package substrate 100. For example, the semiconductor chips 200 may include a first semiconductor chip 200-1, a second semiconductor chip 200-2, a third semiconductor chip 200-3, and a fourth semiconductor chip 200-4. Although the semiconductor package 1000 includes four semiconductor chips, the number of semiconductor chips is not limited to four. For example, the semiconductor package 1000 may include three or less semiconductor chips or at least five semiconductor chips.

The first to fourth semiconductor chips 200-1 to 200-4 may be sequentially stacked in a stepped structure on the package substrate 100. In the semiconductor package 1000, the first semiconductor chip 200-1 and the second semiconductor chip 200-2 may each exchange signals with the package substrate 100 through a first channel CH1. The third semiconductor chip 200-3 and the fourth semiconductor chip 200-4 may each exchange signals with the package substrate 100 through a second channel CH2.

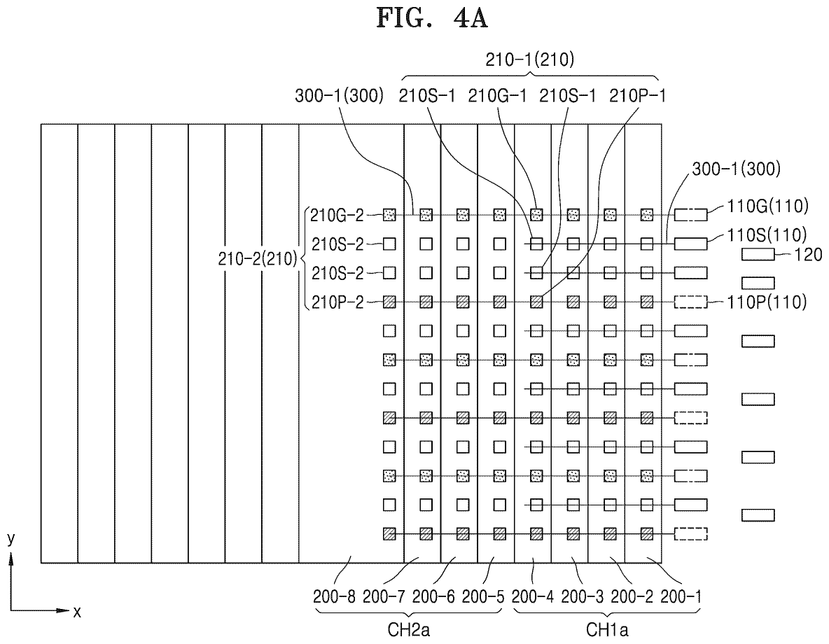

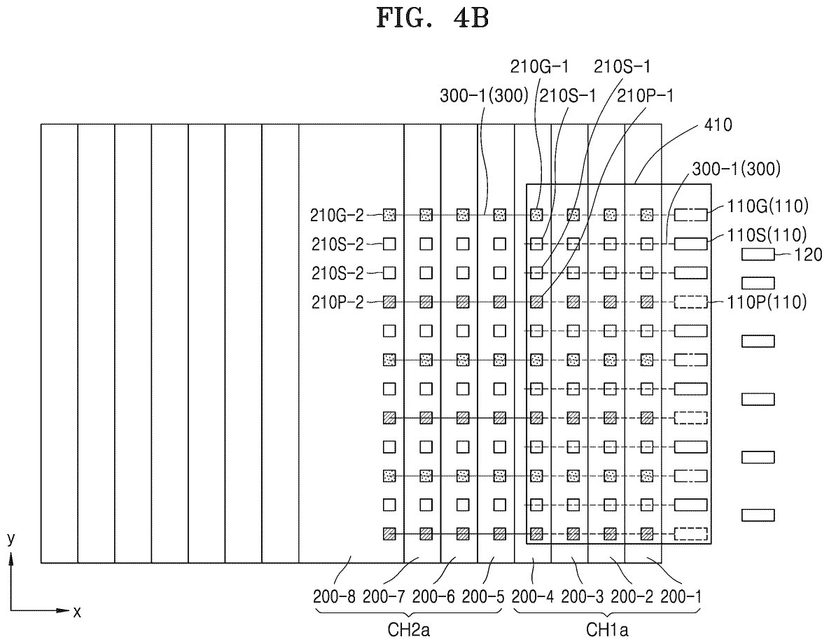

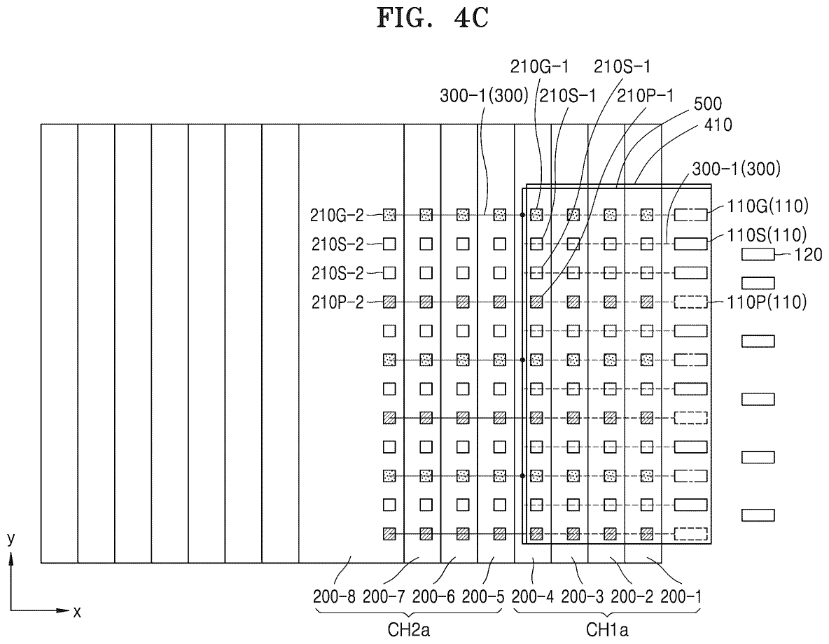

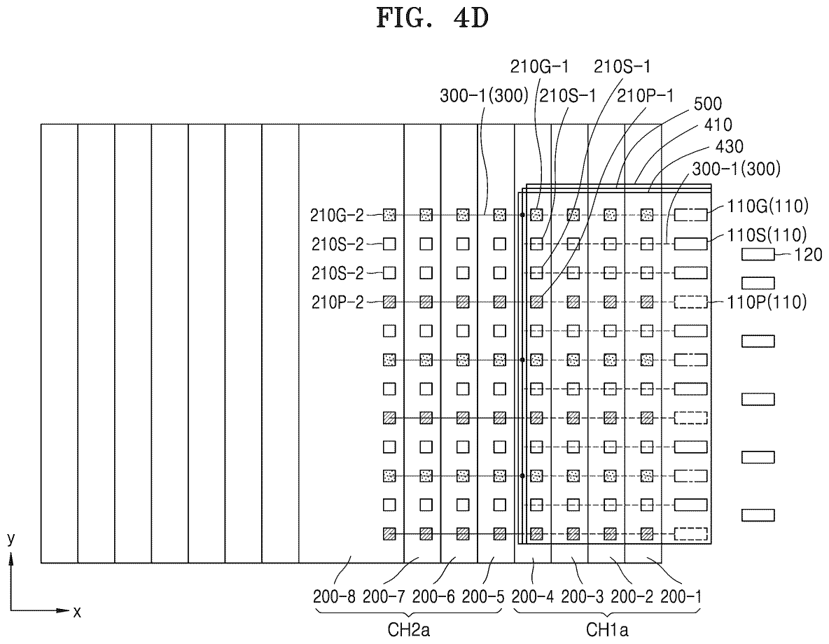

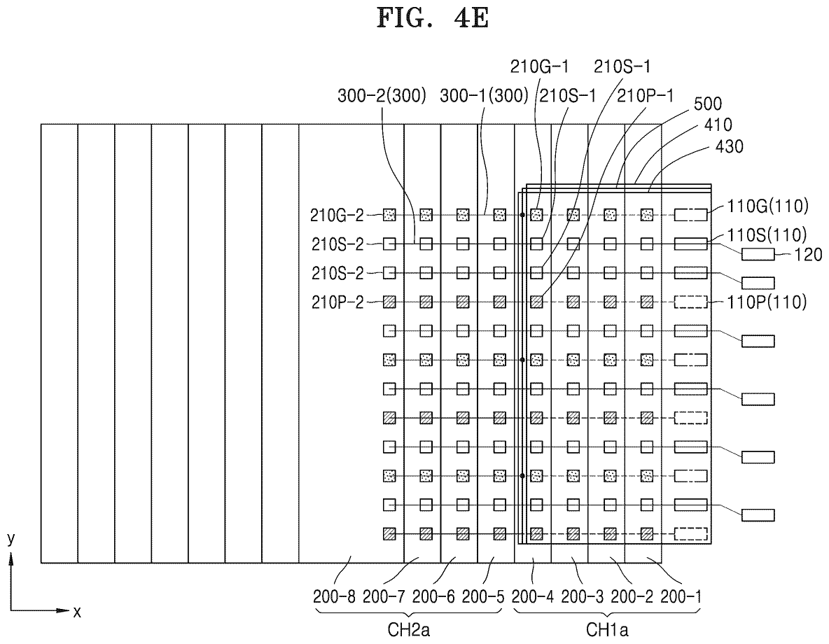

Here, the first channel CH1 and the second channel CH2 may be distinguished by semiconductor chips. Distinction between the first channel CH1 and the second channel CH2 may be practically meaningful in signal transmission. However, since all power is connected together and all ground is connected together, channel distinction may not be very meaningful for power and ground. Four semiconductor chips, i.e., the first to fourth semiconductor chips 200-1 to 200-4, may have substantially the same size, structure, and chip pad position. However, for channel distinction, a chip pad 210 of each of the first semiconductor chip 200-1 and the second semiconductor chip 200-2, which use the first channel CH1, is referred to as a first chip pad 210-1 (see FIG. 4A), and a chip pad 210 of each of the third semiconductor chip 200-3 and the fourth semiconductor chip 200-4, which use the second channel CH2, is referred to as a second chip pad 210-2 (see FIG. 4A). Hereinafter, the description of a channel is excluded. For convenience of description, the first semiconductor chip 200-1 is described, and the discussion thereof is equally applicable to semiconductor chips 200-2, 200-3, and 200-4.

The first semiconductor chip 200-1 may include a chip body layer and the first chip pad 210-1. The chip body layer may include a semiconductor substrate, an integrated device layer, a multi-wiring layer, etc. The semiconductor substrate may be based on a semiconductor material such as a silicon wafer. The integrated device layer may be formed on the semiconductor substrate and may include various types of devices. For example, the integrated device layer may include various kinds of active devices and/or passive devices, such as a transistor, memory devices, logic devices, a system large scale integration (LSI), a complementary metal-oxide-semiconductor (CMOS) image sensor (CIS), and a micro-electro-mechanical system (MEMS).

For example, a transistor may include a bipolar junction transistor (BJT) or a field-effect transistor (FET), such as a planar FET or a FinFET. For example, memory devices may include volatile memory devices, such as dynamic random access memory (DRAM) devices or static RAM (SRAM) devices, or non-volatile memory devices, such as flash memory devices, electrically erasable programmable read-only memory (EEPROM), phase-change RAM (PRAM) devices, magnetoresistive RAM (MRAM) devices, ferroelectric RAM (FeRAM) devices, or resistive RAM (RRAM) devices.

For example, logic devices may include an AND gate, a NAND gate, an OR gate, a NOR gate, an exclusive OR (XOR) gate, an exclusive NOR (XNOR) gate, an inverter (INV), an adder (ADD), a delay (DLY), a filter (FIL), a multiplexer (MXT/MXIT), an OR/AND/inverter (OAI) gate, an AND/OR (AO) gate, an AND/OR/inverter (AOI) gate, a D flip-flop, a reset flip-flop, a master-slave flip-flop, a latch, a counter, or a buffer. Logic devices may perform various kinds of signal processing, such as analog signal processing, analog-to-digital conversion, and control.

For example, in the semiconductor package 1000, the first semiconductor chip 200-1 may include memory devices, e.g., DRAM devices, in the integrated device layer thereof. Accordingly, the first semiconductor chip 200-1 may correspond to a DRAM chip. However, in the semiconductor package 1000, the type of first semiconductor chip 200-1 is not limited to a DRAM chip. The top surface of the chip body layer may be covered and protected by a chip protection layer. For example, the chip protection layer may include an insulating layer, such as an oxide layer or a nitride layer. However, the material of the chip protection layer is not limited those material mentioned above.

The first chip pad 210-1 may be on the top surface of the first semiconductor chip 200-1. Accordingly, the top surface of the first semiconductor chip 200-1 may correspond to an active surface, and the bottom surface of the first semiconductor chip 200-1 may correspond to an inactive surface. The first chip pad 210-1 may be arranged more biased to one side than the other in the x-direction. For example, a plurality of first chip pads 210-1 may arranged in the y-direction to be adjacent to the right edge of the first semiconductor chip 200-1 in the x-direction. When the top surface of the first semiconductor chip 200-1 has a rectangular shape, the first chip pads 210-1 may be arranged in the y-direction to be adjacent to the right edge of the rectangular shape in the x-direction.

The first chip pads 210-1 may include a first signal chip pad 210S-1, a first power chip pad 210P-1 (see FIG. 4A), and a first ground chip pad 210G-1 according to functions. As the terms indicate, a signal may be transmitted through the first signal chip pad 210S-1, power may be transmitted to the first power chip pad 210P-1, and the ground may be transmitted to the first ground chip pad 210G-1. Because the first semiconductor chip 200-1 uses the first channel CH1, the first signal chip pad 210S-1 may be used for signal transmission of the first channel CH1.

The second semiconductor chip 200-2 may include first chip pads 210-1 that may include a first signal chip pad 210S-1, a first power chip pad 210P-1, and a first ground chip pad 210G-1. Each of the third semiconductor chip 200-3 and the fourth semiconductor chip 200-4 may include second chip pads 210-2 that may include a second signal chip pad 210S-2, a second power chip pad 210P-2 (see FIG. 4A), and a second ground chip pad 210G-2.

The first semiconductor chip 200-1 may be bonded and fixed to the top surface of the package substrate 100 through an adhesive layer and thus stacked on the package substrate 100. Each of the second to fourth semiconductor chips 200-2 to 200-4 may also be stacked on a semiconductor chip 200 directly therebelow through an adhesive layer. Each of the second to fourth semiconductor chips 200-2 to 200-4 may be stacked on a semiconductor chip 200 therebelow in a step-wise manner such that a chip pad 210 of each of the first to third semiconductor chips 200-1 to 200-3 may be exposed. For example, the adhesive layer may include a die attach film (DAF). However, the adhesive layer is not limited to the DAF. For convenience, the adhesive layer is not shown in FIGS. 1A to 1C.

The printed wiring 300 may connect chip pads 210 of the semiconductor chip 200 to the substrate pads (110 and 120) of the package substrate 100. The printed wiring 300 may include the first printed wiring 300-1 and the second printed wiring 300-2. The first printed wiring 300-1 may connect a first chip pad 210-1 of each of the first semiconductor chip 200-1 and the second semiconductor chip 200-2 to the first substrate pad 110 of the package substrate 100. The first printed wiring 300-1 may connect each of the second power chip pad 210P-2 and the second ground chip pad 210G-2 among the second chip pads 210-2 of each of the third semiconductor chip 200-3 and the fourth semiconductor chip 200-4 to the first substrate pad 110 of the package substrate 100. The second printed wiring 300-2 may connect the second signal chip pad 210S-2 among the second chip pads 210-2 of each of the third semiconductor chip 200-3 and the fourth semiconductor chip 200-4 to the second substrate pad 120 of the package substrate 100.

As shown in FIGS. 1A to 1C, the printed wiring 300 may extend from a chip pad 210 of an upper semiconductor chip 200 to its corresponding substrate pad (e.g., 110 or 120) of the package substrate 100 via a chip pad 210 of a lower semiconductor chip 200. The first printed wiring 300-1 may extend from the first signal chip pad 210S-1 of the second semiconductor chip 200-2 to a first signal substrate pad 110S (see FIG. 4A) of the package substrate 100 via the first signal chip pad 210S-1 of the first semiconductor chip 200-1. The first printed wiring 300-1 may also extend from the second power chip pad 210P-2 of the fourth semiconductor chip 200-4 to a first power substrate pad 110P (see FIG. 4A) of the package substrate 100 via the second power chip pad 210P-2 of the third semiconductor chip 200-3, the first power chip pad 210P-1 of the second semiconductor chip 200-2, and the first power chip pad 210P-1 of the first semiconductor chip 200-1. The first printed wiring 300-1 may also extend from the second ground chip pad 210G-2 of the fourth semiconductor chip 200-4 to a first ground substrate pad 110G (see FIG. 4A) of the package substrate 100 via the second ground chip pad 210G-2 of the third semiconductor chip 200-3, the first ground chip pad 210G-1 of the second semiconductor chip 200-2, and the first ground chip pad 210G-1 of the first semiconductor chip 200-1. The second printed wiring 300-2 may extend from the second signal chip pad 210S-2 of the fourth semiconductor chip 200-4 to the second substrate pad 120 of the package substrate 100 via the second signal chip pad 210S-2 of the third semiconductor chip 200-3.

The first printed wiring 300-1 connected to the first signal chip pad 210S-1 and the second printed wiring 300-2 connected to the second signal chip pad 210S-2 may overlap each other in an overlapping region OLA. Here, as shown in FIG. 1A, the overlapping region OLA may include a region from the first chip pad 210-1 of the second semiconductor chip 200-2 to the first substrate pad 110 of the package substrate 100 in the x-direction. Accordingly, in a typical semiconductor package structure, crosstalk between a signal of the first channel CH1 using the first printed wiring 300-1 and a signal of the second channel CH2 using the second printed wiring 300-2 may occur in the overlapping region OLA. However, in the semiconductor package 1000 of some example embodiments, the multi-isolation layer MIL may be arranged between the first printed wiring 300-1 and the second printed wiring 300-2 in the overlapping region OLA so that signal crosstalk may be minimized or reduced. Accordingly, signal characteristics may be improved. In addition, a return path effect on a signal may increase due to a ground layer 500 of the multi-isolation layer MIL so that a loop inductance value may be reduced. Consequently, the semiconductor package 1000 may provide signal integrity (SI) for high-speed operation by improving signal characteristics and reducing a loop inductance value by including the multi-isolation layer MIL in the overlapping region OLA. The structure of the multi-isolation layer MIL is explained in detail in the description of the multi-isolation layer MIL below.

In the semiconductor package 1000, the printed wiring 300 may be formed through direct printing using conductive ink or conductive paste. Here, the direct printing may include various printing methods, such as ink-jet printing, dispensing printing, aerosol jet printing, electro-hydrodynamic (EHD) printing, and screen printing.

Conductive ink may result from dispersion of a conductive filler in a vehicle. A hardened film of printed conductive ink exhibits conductivity. The conductive ink may be manufactured by mixing an additive, a solvent, and resin into the conductive filler. The conductive filler may be referred to as metal powder and may include silver (Ag), copper (Cu), nickel (Ni), carbon (C), or aluminum (Al). However, the type of conductive filler is not limited to those materials mentioned above. The printed wiring 300 may have a conductive filler content of at least 80 wt %. However, the conductive filler content is not limited thereto.

The resin may form the vehicle together with the solvent. For example, the resin may include epoxy, silicon, urethane, or polyimide-based resin. However, the material of the resin is not limited to those mentioned above. For example, the solvent may include an organic solvent.

The additive may be used to impart various characteristics to the printed wiring 300. For example, the additive may be used to impart a characteristic, such as flexibility, an anti-static characteristic, or flow prevention, to the printed wiring 300. For example, in the semiconductor package 1000, the printed wiring 300 may include an additive increasing flexibility. As the flexibility of the printed wiring 300 is increased by the additive, cracks may be limited or prevented from occurring in a bend portion of the printed wiring 300.

In the semiconductor package 1000, the printed wiring 300 may be formed through direct printing. Accordingly, compared to a semiconductor package having a wire bonding structure, the pitch of the chip pads 210 of the semiconductor chip 200 may be reduced. In other words, in the case of a semiconductor package having a wire bonding structure, there is a limit to the reduction of the pitch of the chip pads 210 due to a wire bonding process. However, in the case of the semiconductor package 1000, direct printing instead of a wire bonding process may be performed so that the pitch of the chip pads of the semiconductor chip 200 may be further reduced.

The multi-isolation layer MIL may minimize or reduce signal crosstalk by shielding a signal of the first channel CH1 and a signal of the second channel CH2. In other words, the multi-isolation layer MIL may be between the first printed wiring 300-1 and the second printed wiring 300-2 in the overlapping region OLA and may minimize or reduce crosstalk between a signal of the first channel CH1 using the first printed wiring 300-1 and a signal of the second channel CH2 using the second printed wiring 300-2. Here, the signal of the first channel CH1 may be transmitted through the first printed wiring 300-1, which connects respective first signal chip pads 210S-1 of the first semiconductor chip 200-1 and the second semiconductor chip 200-2 to the first signal substrate pad 110S of the package substrate 100. The signal of the second channel CH2 may be transmitted through the second printed wiring 300-2, which connects respective second signal chip pads 210S-2 of the third semiconductor chip 200-3 and the fourth semiconductor chip 200-4 to the second substrate pad 120 of the package substrate 100. The first printed wiring 300-1 used to transmit a signal of the first channel CH1 and the second printed wiring 300-2 used to transmit a signal of the second channel CH2 may overlap each other in the overlapping region OLA. As described above, the overlapping region OLA may include a region from the first chip pad 210-1 of the second semiconductor chip 200-2 to the first substrate pad 110 of the package substrate 100 in the x-direction.

The multi-isolation layer MIL may include an isolation insulating layer 400 and a ground layer 500. The isolation insulating layer 400 may include a lower isolation insulating layer 410 and an upper isolation insulating layer 430. The lower isolation insulating layer 410 may cover the first printed wiring 300-1 in the overlapping region OLA. The lower isolation insulating layer 410 may have a sheet shape covering most of the overlapping region OLA. The sheet shape of the lower isolation insulating layer 410 may include a bent portion having a step shape in correspondence to a stepped structure of the first semiconductor chip 200-1 and the second semiconductor chip 200-2.

The ground layer 500 may cover the lower isolation insulating layer 410 in the overlapping region OLA. The ground layer 500 may have a sheet shape covering most of the overlapping region OLA. The sheet shape of the ground layer 500 may include a bent portion having a step shape in correspondence to a stepped structure of the first semiconductor chip 200-1 and the second semiconductor chip 200-2.

As seen in a contact point CP marked with a long-short dashed line oval in FIG. 1B, the ground layer 500 may be connected to the first printed wiring 300-1 connected to the ground. Accordingly, a ground voltage may be applied to the ground layer 500. The ground layer 500 may be connected to the first printed wiring 300-1 between the second ground chip pad 210G-2 of the third semiconductor chip 200-3 and the first ground chip pad 210G-1 of the second semiconductor chip 200-2. Assuming a structure having at least five semiconductor chips 200, the ground layer 500 may be connected to the first printed wiring 300-1 between the second ground chip pad 210G-2 of the bottommost semiconductor chip 200 among semiconductor chips 200 using the second channel CH2 and the first ground chip pad 210G-1 of the topmost semiconductor chip 200 among semiconductor chips using the first channel CH1. Although the ground layer 500 is connected to the first printed wiring 300-1 at a side of the third semiconductor chip 200-3 in FIG. 1B, example embodiments are not limited thereto. The ground layer 500 may be connected to the first printed wiring 300-1 on the exposed top surface of the second semiconductor chip 200-2. In this case, an upper end portion of the lower isolation insulating layer 410 may be shorter than that shown in FIG. 1B in the x-direction.

The ground layer 500 may include a conductive material, e.g., metal. In the semiconductor package 1000, the ground layer 500 may include copper (Cu). However, the material of the ground layer 500 is not limited to Cu.

The upper isolation insulating layer 430 may cover the ground layer 500 in the overlapping region OLA. The upper isolation insulating layer 430 may have a sheet shape covering most of the overlapping region OLA. The sheet shape of the upper isolation insulating layer 430 may include a bent portion having a step shape in correspondence to the stepped structure of the first semiconductor chip 200-1 and the second semiconductor chip 200-2. The upper isolation insulating layer 430 may include a cover 432 on the package substrate 100 to cover an end portion of the ground layer 500. The cover 432 may prevent or limit the second printed wiring 300-2 from contacting the ground layer 500. In some example embodiments, the cover 432 may be omitted. When the cover 432 is omitted, a lower end portion of the upper isolation insulating layer 430 may extend further than an end of the ground layer 500 in the x-direction.

The isolation insulating layer 400 may include an insulating material. As seen in FIGS. 1B and 1C, the isolation insulating layer 400 may be between a semiconductor chip 200 and the sealant 600. Accordingly, in terms of minimizing or reducing warpage of the semiconductor package 1000, the isolation insulating layer 400 may include an insulating material having the coefficient of thermal expansion that is at least the coefficient of thermal expansion of the semiconductor chip 200 but not more than the coefficient of thermal expansion of the sealant 600. For example, in the semiconductor package 1000, the isolation insulating layer 400 may include epoxy or various types of resin or adhesive used for underfill.

The sealant 600 may cover the top and side surfaces of the semiconductor chip 200 on the package substrate 100, the printed wiring 300, and the multi-isolation layer MIL. The sealant 600 may cover the top surface of the fourth semiconductor chip 200-4 to a certain or desired thickness. The sealant 600 may include thermosetting resin such as epoxy resin, thermoplastic resin such as polyimide, or resin including a reinforcing material such as an inorganic filler. For example, the sealant 600 may include an Ajinomoto build-up film (ABF), FR-4, or BT. The sealant 600 may include a molding material, such as an epoxy mold compound (EMC), or a photosensitive material, such as a photo-imageable encapsulant (PIE). However, the material of the sealant 600 is not limited to those mentioned above.

An external connection terminal may be arranged on the bottom surface of the package substrate 100. The external connection terminal may be electrically connected to the wiring of the package substrate 100 through an external pad. For example, the external connection terminal may include a solder ball. However, according to some example embodiments, the external connection terminal may include a pillar and solder. The semiconductor package 1000 may be mounted on an external substrate, such as an interposer or a base substrate, through the external connection terminal of the package substrate 100.

In the semiconductor package 1000, a plurality of semiconductor chips 200 may be arranged on the package substrate 100 in a stepped structure and may exchange signals with the package substrate 100 through two channels using the printed wiring 300. In addition, the multi-isolation layer MIL may be arranged between the first printed wiring 300-1 and the second printed wiring 300-2 in the overlapping region OLA in which the first printed wiring 300-1 and the second printed wiring 300-2 overlap each other. The multi-isolation layer MIL may include the lower isolation insulating layer 410, the ground layer 500, and the upper isolation insulating layer 430, which are sequentially stacked. The semiconductor package 1000 may minimize or reduce crosstalk between a signal of the first channel CH1 and a signal of the second channel CH2 by using the multi-isolation layer MIL arranged in the overlapping region OLA so that signal characteristics may be improved. In addition, a return path effect on a signal may increase due to the ground layer 500 of the multi-isolation layer MIL so that a loop inductance value may be reduced. Accordingly, the semiconductor package 1000 may secure SI for high-speed operation by improving signal characteristics and reducing a loop inductance value by using the multi-isolation layer MIL in the overlapping region OLA.

Furthermore, compared to a semiconductor package having a wire bonding structure, the semiconductor package 1000 may have a reduced height by using the printed wiring 300. For example, the semiconductor package 1000 may have a height reduced by a loop height by which a wire connected to a topmost semiconductor chip rises upward from the topmost semiconductor chip in a semiconductor package having a wire bonding structure. Additionally, because the printed wiring 300 is in contact with the top surface of a semiconductor chip 200 via direct printing in the semiconductor package 1000, a fine pitch of chip pads 210 may be embodied. Because the printed wiring 300 is in contact with the top surface of the package substrate 100 and with the top or side surface of the semiconductor chip 200, occurrence of wire sweeping may be prevented or reduced in a molding process.

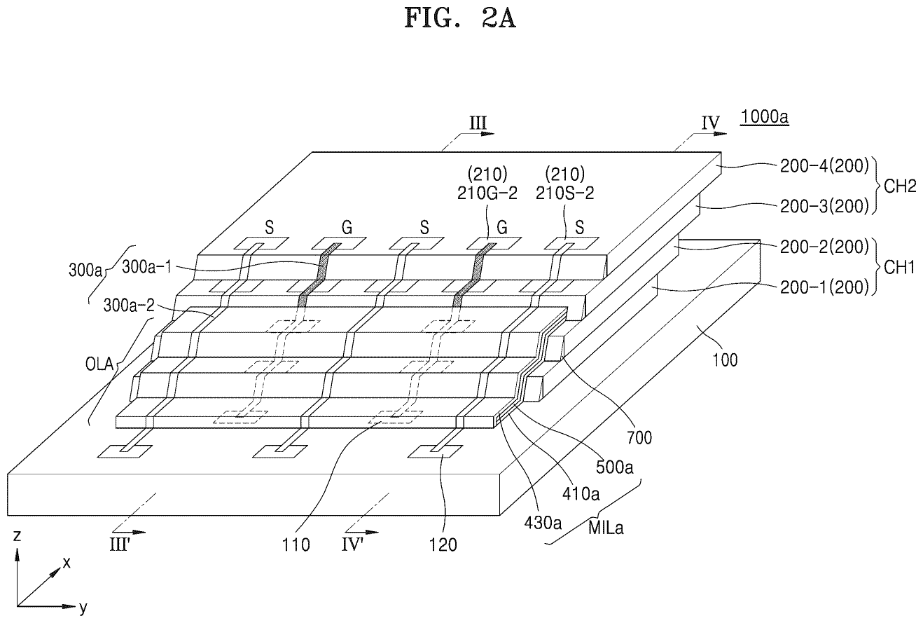

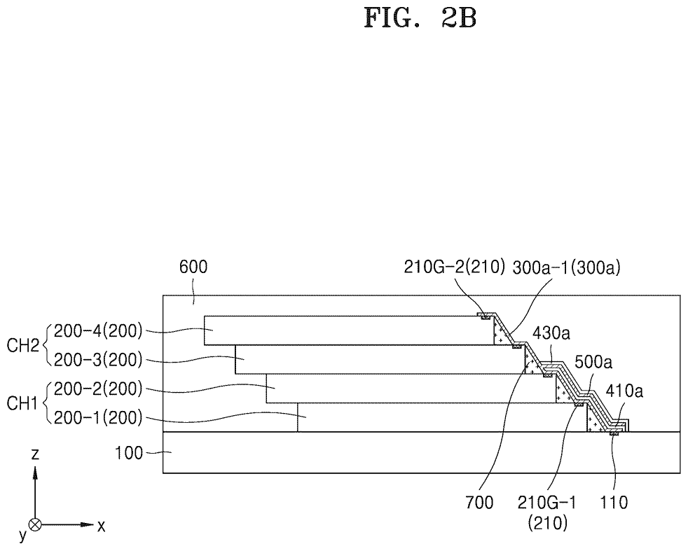

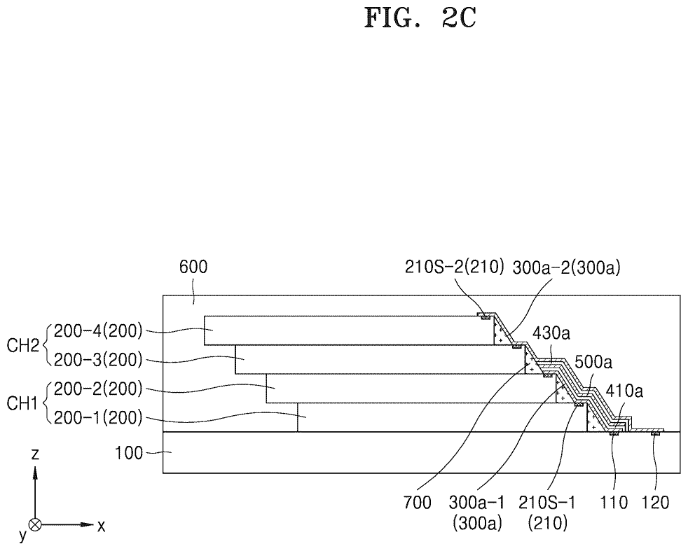

FIGS. 2A to 2C are a schematic perspective view and cross-sectional views of a semiconductor package 1000a, according to some example embodiments. FIG. 2B is a cross-sectional view taken along line III-III′ in FIG. 2A. FIG. 2C is a cross-sectional view taken along line IV-IV′ in FIG. 2A. A sealant (e.g., sealant 600) is not shown in FIG. 2A for clarity of illustration. The semiconductor package 1000a may be same as or similar in some respects to the semiconductor package 1000a of FIGS. 1A-1C, and therefore may be best understood with reference thereto where like numerals indicate like elements not described again in detail.

Referring to FIGS. 2A to 2C, the semiconductor package 1000a may include a side insulating layer 700. The semiconductor package 1000a may include the package substrate 100, a semiconductor chip 200, a printed wiring 300a, a multi-isolation layer MILa, the sealant 600, and the side insulating layer 700. The descriptions of the package substrate 100, the semiconductor chip 200, the printed wiring 300a, the multi-isolation layer MILa, and the sealant 600 are the same as or similar in some respects to the description of the corresponding components of the semiconductor package 1000 of FIGS. 1A to 1C. However, as the side insulating layer 700 is arranged on a side surface of the semiconductor chip 200, the printed wiring 300a may have a changed shape extending along an inclined surface of the side insulating layer 700. In addition, the structure of the multi-isolation layer MILa may have a changed shape covering the inclined surface of the side insulating layer 700. For example, a lower isolation insulating layer 410a of the multi-isolation layer MILa may have a changed shape covering the inclined surface of the side insulating layer 700 in the overlapping region OLA, a ground layer 500a may have a changed shape covering the lower isolation insulating layer 410a, and an upper isolation insulating layer 430a may have a changed shape covering the ground layer 500a.

The side insulating layer 700 may be arranged on a side surface of the semiconductor chip 200. The side insulating layer 700 may be arranged on the package substrate 100 and on the right side surface of the first semiconductor chip 200-1 in the x-direction. The side insulating layer 700 may also be arranged on a semiconductor chip 200 below each of the second to fourth semiconductor chips 200-2 to 200-4 and on the right side surface of each of the second to fourth semiconductor chips 200-2 to 200-4 in the x-direction. The side insulating layer 700 may extend in the y-direction and cover the right side surface of a semiconductor chip 200 and a portion of the top surface of the package substrate 100 below the semiconductor chip 200 or a portion of the top surface of another semiconductor chip 200 below the current semiconductor chip 200.

The side insulating layer 700 may have a shape of a triangular pillar extending in the y-direction. As shown in FIGS. 2B and 2C, a cross-section of the side insulating layer 700, taken in a direction that is perpendicular to the y-direction, may have a shape of a right triangle. A side surface of the side insulating layer 700, which corresponds to the height of the right triangle, may be in contact with the right side surface of the semiconductor chip 200. The bottom surface of the side insulating layer 700, which corresponds to the bottom side of the right triangle, may be in contact with the top surface of the package substrate 100, on which the semiconductor chip 200 is arranged, or with the top surface of another semiconductor chip 200 below the current semiconductor chip 200.

The side insulating layer 700 may be arranged between the semiconductor chip 200 and the sealant 600 or between the semiconductor chip 200 and the multi-isolation layer MILa. Accordingly, in terms of minimizing or reducing warpage of the semiconductor package 1000a, the side insulating layer 700 may include an insulating material having the coefficient of thermal expansion that is at least the coefficient of thermal expansion of the semiconductor chip 200 but not more than the coefficient of thermal expansion of the sealant 600. For example, similar to the isolation insulating layer 400a, the side insulating layer 700 may include epoxy or various types of resin or adhesive used for underfill in the semiconductor package 1000a.

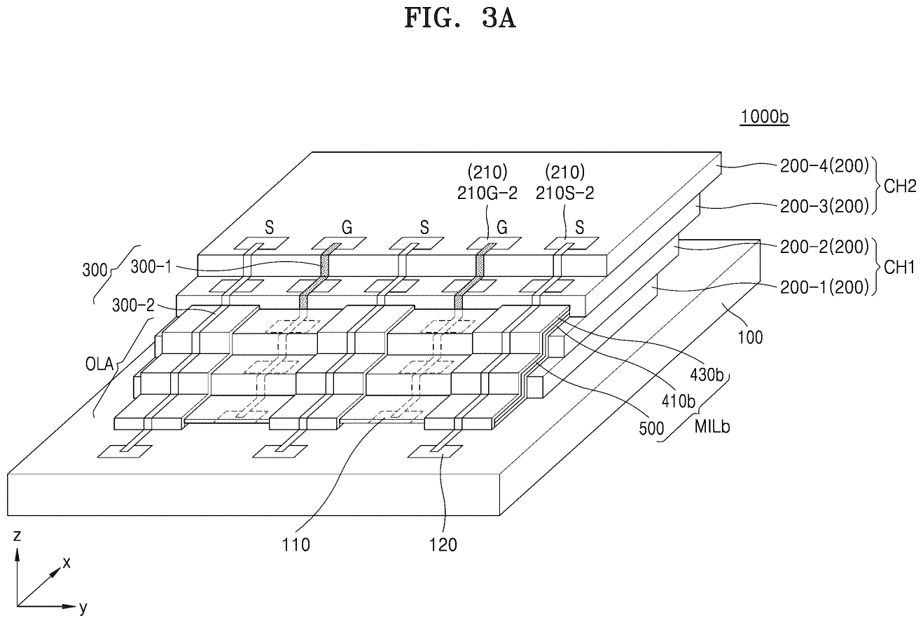

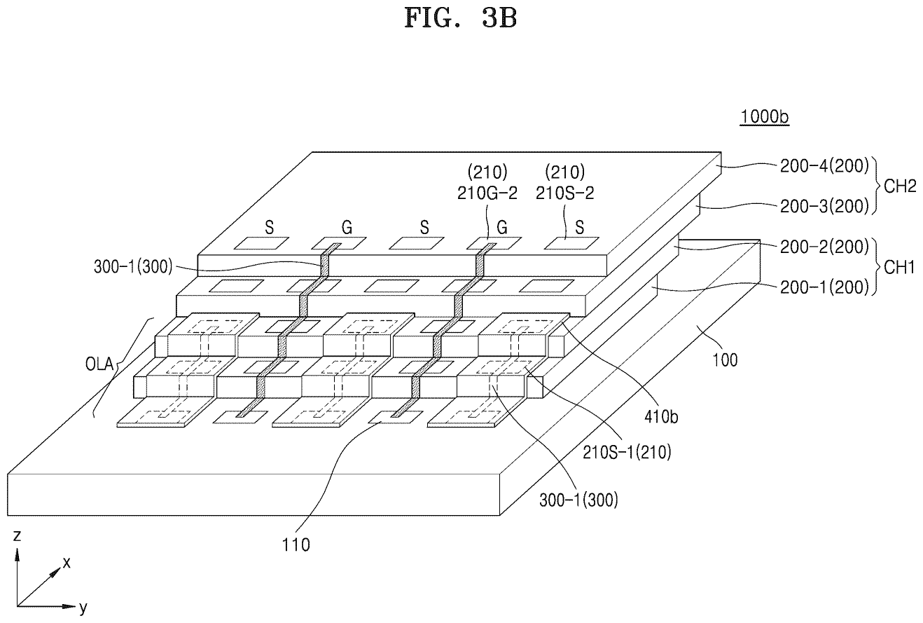

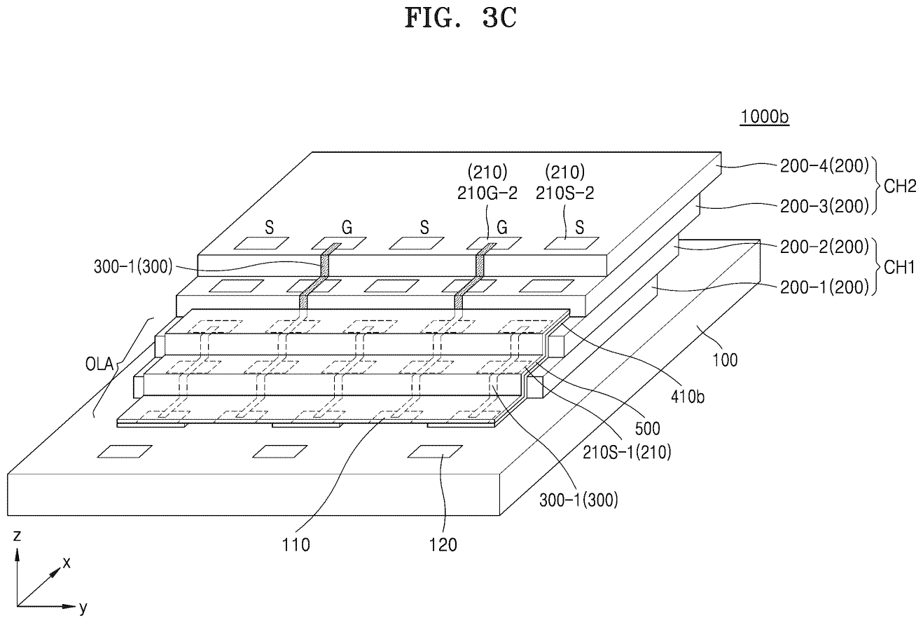

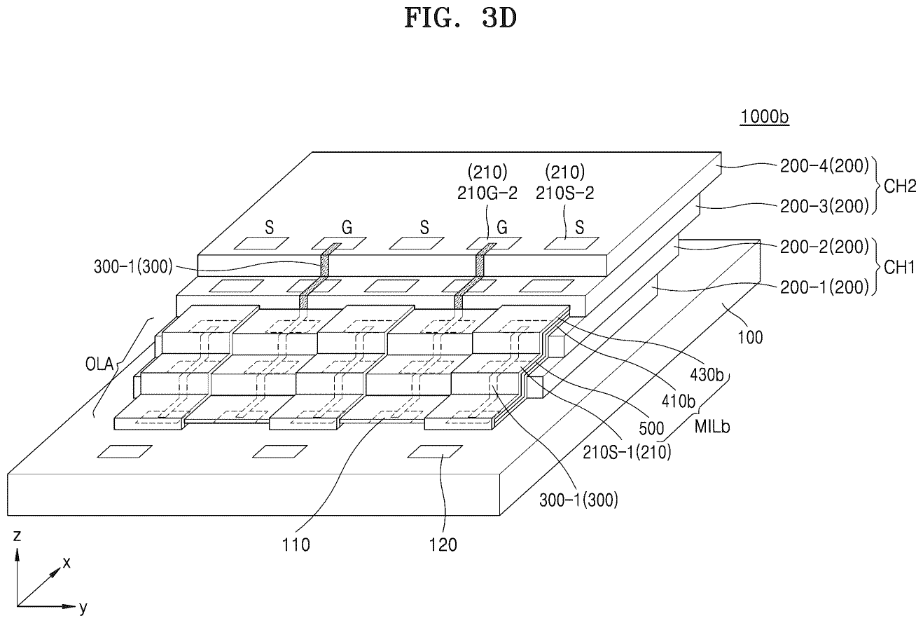

FIGS. 3A to 3D are schematic perspective views of a semiconductor package 1000b according to some example embodiments. FIGS. 3B to 3D are perspective views, from which some components of the semiconductor package of FIG. 3A are omitted to show in detail the shape of a multi-insulation layer. A sealant (e.g., sealant 600) is not shown in the perspective view of FIG. 3A for sake of clarity of illustration. The semiconductor package 1000b may be same as or similar in some respects to the semiconductor packages 1000a and 1000b of FIGS. 1A-2C, and therefore may be best understood with reference thereto where like numerals indicate like elements not described again in detail.

Referring to FIGS. 3A to 3D, the semiconductor package 1000b may include the package substrate 100, the semiconductor chip 200, the printed wiring 300, the multi-isolation layer MILb, and the sealant 600. The descriptions of the package substrate 100, the semiconductor chip 200, the printed wiring 300, and the sealant 600 are the same as or similar in some respect to the corresponding components of the semiconductor package 1000 of FIGS. 1A to 1C.

In the semiconductor package 1000b, the multi-isolation layer MILb may include a lower isolation insulating layer 410b, the ground layer 500, and an upper isolation insulating layer 430b. As shown in FIG. 3B, the lower isolation insulating layer 410b may have a line band shape in the overlapping region OLA and cover the first printed wiring 300-1 connected to the first signal chip pad 210S-1. In other words, the lower isolation insulating layer 410b may have a line band shape, which individually covers the first printed wiring 300-1 connected to the first signal chip pad 210S-1, rather than a sheet shape covering most of the overlapping region OLA. FIG. 3B shows a state before the ground layer 500, the upper isolation insulating layer 430b, and the second printed wiring 300-2 are formed. A lower isolation insulating layer 410b may have a line band shape covering a first printed wiring 300-1 connected to power.

As shown in FIG. 3C, the ground layer 500 may have a sheet shape and cover the lower isolation insulating layer 410b, similar to the structure of the multi-isolation layer MIL of the semiconductor package 1000 of FIG. 1A. However, as the lower isolation insulating layer 410b is arranged below the ground layer 500, the ground layer 500 may have a bent portion according to the line band shape of the lower isolation insulating layer 410b. In other words, the ground layer 500 may be divided into a portion covering the lower isolation insulating layer 410b and a portion directly covering the semiconductor chip 200, and the top surface of the portion directly covering the semiconductor chip 200 may be lower than the top surface of the portion of the covering the lower isolation insulating layer 410b. FIG. 3C shows a state before the upper isolation insulating layer 430b and the second printed wiring 300-2 are formed.

In the semiconductor package 1000b, the ground layer 500 may also be connected to the first printed wiring 300-1 connected to the ground. The ground layer 500 may be connected to a first portion of the first printed wiring 300-1 between a second ground chip pad 210G-2 of the third semiconductor chip 200-3 and a first ground chip pad 210G-1 of the second semiconductor chip 200-2 and to a second portion of the first printed wiring 300-1 below the first portion. In other words, the ground layer 500 may be connected to the whole of the first printed wiring 300-1, which is connected to the ground, in the overlapping region OLA.

As shown in FIG. 3D, the upper isolation insulating layer 430b may have a line band shape in the overlapping region OLA and may cover a portion of the ground layer 500 corresponding to the second printed wiring 300-2. In other words, similar to the structure of the lower isolation insulating layer 410b, the upper isolation insulating layer 430b may have a line band shape covering a portion of the ground layer 500 rather than a sheet shape covering most of the overlapping region OLA. The position of the upper isolation insulating layer 430b may be the same as or similar in some respects to the position of the lower isolation insulating layer 410b. The size of the lower isolation insulating layer 410b may be the same as the size of the upper isolation insulating layer 430b. However, example embodiments are not limited thereto. In some example embodiments, the lower isolation insulating layer 410b and the upper isolation insulating layer 430b may be different sizes from each other. FIG. 3D shows a state before the second printed wiring 300-2 is formed on the upper isolation insulating layer 430b.

In some example embodiments, only one of the lower isolation insulating layer 410b and the upper isolation insulating layer 430b may have a line band shape, and the other one may have a sheet shape. In some example embodiments, the ground layer 500 may also have a line band shape and may be arranged between the lower isolation insulating layer 410b and the upper isolation insulating layer 430b. However, when the ground layer 500 has a line band shape, an additional printed wiring may be further arranged to connect the ground layer 500 to the first printed wiring 300-1 connected to the ground.

Although the semiconductor packages 1000, 1000a, and 1000b using two channels have been described above, the number of channels is not limited to two. For example, three or more channels may be used in some example embodiments. When three channels are used, the layered structure of a multi-isolation layer may be changed. For example, in a semiconductor package using three channels, a multi-isolation layer may include four isolation insulating layers and two ground layers. Two lower isolation insulating layers and one lower ground layer may form a structure similar to the structure of the multi-isolation layer MIL, MILa, or MILb of the semiconductor package 1000, 1000a, or 1000b described above. Upper two isolation insulating layers and upper one ground layer may be arranged in an upper overlapping region, in which a printed wiring of a second channel overlaps a printed wiring of a third channel, and between the printed wiring of the second channel and the printed wiring of the third channel. In the upper overlapping region, the upper two isolation insulating layers and the upper one ground layer may cover the printed wiring of the second channel, and the printed wiring of the third channel may be arranged on the top surface of the topmost isolation insulating layer.

FIGS. 4A to 4E are plan views schematically illustrating a method of manufacturing a semiconductor package, according to some example embodiments. The method of FIGS. 4A-4E may be best understood with reference to FIGS. 1A-3D where like numerals indicate like elements not described again in detail.

Referring to FIG. 4A, semiconductor chips 200 may be stacked in a stepped structure on the package substrate 100. For example, each of the semiconductor chips 200 may be stacked on the package substrate 100 or another semiconductor chip 200 therebelow through an adhesive layer. The semiconductor chips 200 may be stacked in a stepped structure such that a chip pad 210 of a lower semiconductor chip 200 is exposed. The package substrate 100 and the semiconductor chips 200 have been explained in the descriptions of the semiconductor package 1000 of FIG. 1A.

As illustrated, in the method of manufacturing a semiconductor package, according to some example embodiments, eight semiconductor chips 200 may be stacked on the package substrate 100. Among the eight semiconductor chips 200, first to fourth semiconductor chips 200-1 to 200-4 may transmit signals through the first channel CH1a, and fifth to eighth semiconductor chips 200-5 to 200-8 may transmit signals through the second channel CH2a. However, the number of semiconductor chips 200 stacked on the package substrate 100 is not limited to eight. The grouping or separation of channels is not limited to that described above, and may be varied depending on application and/or design. For example, in some example embodiments, seven or less semiconductor chips 200 or at least nine semiconductor chips 200 may be stacked on the package substrate 100, and the grouping of channels may be adjusted according to the total number of semiconductor chips 200.

The first to fourth semiconductor chips 200-1 to 200-4 using the first channel CH1a may each include first chip pads 210-1, and the fifth to eighth semiconductor chips 200-5 to 200-8 using the second channel CH2a may each include second chip pads 210-2. The arranged order of first chip pads 210-1 in the y-direction may be substantially the same as the arrangement order of second chip pads 210-2 in the y-direction. The first chip pads 210-1 may include a first signal chip pad 210S-1, a first ground chip pad 210G-1, and a first power chip pad 210P-1. The second chip pads 210-2 may include a second signal chip pad 210S-2, a second power chip pad 210P-2, and a second ground chip pad 210G-2. For example, in FIG. 4A, each of the empty small squares on the semiconductor chips 200 may correspond to the first signal chip pad 210S-1 or the second signal chip pad 210S-2. Each of the hatched small squares may correspond to the first power chip pad 210P-1 or the second power chip pad 210P-2. Each of the dotted small squares may correspond to the first ground chip pad 210G-1 or the second ground chip pad 210G-2.

First substrate pads 110 and second substrate pads 120 may be arranged in the y-direction on the package substrate 100. The first substrate pads 110 may be closer to the semiconductor chips 200 than the second substrate pads 120 in the x-direction. The first substrate pads 110 may include first signal substrate pads 110S each marked with a solid line rectangle, first power substrate pads 110P each marked with a dashed line rectangle, and first ground substrate pads 110G each marked with a long-short dashed line rectangle. All of the second substrate pads 120 may correspond to second signal substrate pads. The arrangement order of the first substrate pads 110 in the y-direction may be substantially the same as the arrangement order of the first chip pads 210-1 or the second chip pads 210-2 in the y-direction.

After the semiconductor chips 200 are stacked, the first signal chip pad 210S-1 of each of the first to fourth semiconductor chips 200-1 to 200-4 using the first channel CH1a may be connected to a first signal substrate pad 110S through the first printed wiring 300-1. Power chip pads (e.g., 210P-1 and 210P-2) of semiconductor chips (e.g., 200-1 to 200-8) using the first channel CH1a and the second channel CH2a may be connected to the first power substrate pad 110P through the first printed wiring 300-1, and ground chip pads (e.g., 210G-1 and 210G-2) of the semiconductor chips (200-1 to 200-8) may be connected to the first ground substrate pad 110G though the first printed wiring 300-1. For example, the first printed wiring 300-1 may be formed through direct printing by using conductive ink or conductive paste.

The first signal chip pad 210S-1 of each of the first to fourth semiconductor chips 200-1 to 200-4 may be connected to the first signal substrate pad 110S through the first printed wiring 300-1. The first power chip pad 210P-1 of each of the first to fourth semiconductor chips 200-1 to 200-4 and the second power chip pad 210P-2 of each of the fifth to eighth semiconductor chips 200-5 to 200-8 may be connected to the first power substrate pad 110P through the first printed wiring 300-1. The first ground chip pad 210G-1 of each of the first to fourth semiconductor chips 200-1 to 200-4 and the second ground chip pad 210G-2 of each of the fifth to eighth semiconductor chips 200-5 to 200-8 may be connected to the first ground substrate pad 110G through the first printed wiring 300-1.

Referring to FIG. 4B, the lower isolation insulating layer 410 may be formed to cover the first printed wiring 300-1 in the overlapping region OLA. The lower isolation insulating layer 410 may have a sheet shape covering the whole of the first printed wiring 300-1 in the overlapping region OLA. Here, the overlapping region OLA may include a region, in which the first chip pads 210-1 of the first to fourth semiconductor chips 200-1 to 200-4 are exposed, and a region, in which the first substrate pads 110 of the package substrate 100 are arranged. A portion of a first printed wiring 300-1, which is connected to the first signal chip pad 210S-1 of each of the first to fourth semiconductor chips 200-1 to 200-4, and respective portions of first printed wirings 300-1, which are respectively connected to the first power chip pad 210P-1 and the first ground chip pad 210G-1 of each of the first to fourth semiconductor chips 200-1 to 200-4, may be arranged in the overlapping region OLA.

The shape of the lower isolation insulating layer 410 is not limited to the sheet shape. For example, the lower isolation insulating layer 410 may have a line band shape covering each of the first printed wirings 300-1 in the overlapping region OLA. However, the lower isolation insulating layer 410 having a line band shape may not cover a first printed wiring 300-1 connected to the ground. Additional description of the lower isolation insulating layer 410 is the same as or similar in some respects to that of the lower isolation insulating layer 410 of the multi-isolation layer MIL of the semiconductor package 1000 of FIG. 1A.

Referring to FIG. 4C, after the lower isolation insulating layer 410 is formed, the ground layer 500 may be formed in the overlapping region OLA to cover the lower isolation insulating layer 410. As shown by block dots in FIG. 4C, the ground layer 500 may be connected to first printed wirings 300-1, which are connected to the ground, between the fourth semiconductor chip 200-4 and the fifth semiconductor chip 200-5. For example, the ground layer 500 may be connected to the first printed wiring 300-1 connected to the second ground chip pad 210G-2 of the fifth semiconductor chip 200-5. Accordingly, a ground voltage may be applied to the ground layer 500. Additional description of the ground layer 500 is the same as or similar in some respects to that of the ground layer 500 of the multi-isolation layer MIL of the semiconductor package 1000 of FIG. 1A.

Referring to FIG. 4D, after the ground layer 500 is formed, the upper isolation insulating layer 430 may be formed in the overlapping region OLA to cover the ground layer 500. The upper isolation insulating layer 430 may be formed to cover the upper end portion of the ground layer 500 in the x-direction. When the upper isolation insulating layer 430 is formed in this structure, a short-circuit may be prevented or limited between the ground layer 500 and a second printed wiring 300-2, which is formed later.

Similar to the lower isolation insulating layer 410, the upper isolation insulating layer 430 may have a sheet shape covering most of the overlapping region OLA. However, the shape of the upper isolation insulating layer 430 is not limited thereto. The upper isolation insulating layer 430 may have a line band shape covering only a portion of the ground layer 500 corresponding to the second printed wiring 300-2 to be formed later. The other description of the upper isolation insulating layer 430 is the same as that of the upper isolation insulating layer 430 of the multi-isolation layer MIL of the semiconductor package 1000 of FIG. 1A.

Referring to FIG. 4E, after the upper isolation insulating layer 430 is formed, the second printed wiring 300-2 may be formed. The second printed wiring 300-2 may connect the second signal chip pad 210S-2 of each of the fifth to eighth semiconductor chips 200-5 to 200-8 to a second substrate pad 120. A portion of the second printed wiring 300-2, which is connected to the second signal chip pad 210S-2, may be arranged on each of the fifth to eighth semiconductor chips 200-5 to 200-8, and a portion of the second printed wiring 300-2 in the overlapping region OLA may be arranged on the upper isolation insulating layer 430.

The second printed wiring 300-2 may be bent on the top surface of the package substrate 100 and connected to the second substrate pad 120. This is because the second substrate pad 120 and the first substrate pad 110 are not aligned with each other in the x-direction but are arranged in a staggered pattern. In some example embodiments, the second substrate pads 120 may be aligned with the first substrate pad 110, e.g., the first signal substrate pad 110S, in the x-direction. In this case, the second printed wiring 300-2 may be connected to the second substrate pad 120 without being bent. Additional description of the second printed wiring 300-2 is the same as or similar in some respects to that of the second printed wiring 300-2 of the semiconductor package 1000 of FIG. 1A.

Thereafter, the sealant 600 may be formed on the package substrate 100 to seal the semiconductor chips 200, and an external connection terminal may be formed on the bottom surface of the package substrate 100 so that the semiconductor package 1000 may be manufactured. The semiconductor package 1000 may correspond to the semiconductor package 1000 of FIG. 1A. The semiconductor package 1000a of FIG. 2A may be manufactured by forming a side insulating layer 700 on a side surface of each of the semiconductor chips 200 before forming the first printed wiring 300-1 and then performing the processes of FIGS. 4A to 4E. The semiconductor package 1000b of FIG. 3A may be manufactured by forming the lower isolation insulating layer 410 in a line band shape in FIG. 4B, forming the upper isolation insulating layer 430 in a line band shape in FIG. 4D, and performing the process of FIG. 4E.

Example embodiments are not necessarily mutually exclusive. For example, some example embodiments may include one or more features described with reference to one or more figures, and may also include one or more other features described with reference to one or more other figures.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A semiconductor package comprising:
a package substrate including a first substrate pad and a second substrate pad;
at least one first semiconductor chip including a plurality of first chip pads and on the package substrate in a stepped structure;
at least one second semiconductor chip including a plurality of second chip pads and on the at least one first semiconductor chip in a stepped structure;
a first printed wiring connecting a portion of the plurality of second chip pads and the plurality of first chip pads to the first substrate pad;
a second printed wiring connecting a remaining portion of the plurality of second chip pads to the second substrate pad;
an isolation insulating layer isolating the first printed wiring from the second printed wiring and covering a portion of the first printed wiring on the at least one first semiconductor chip in an overlapping region in which the first printed wiring overlaps the second printed wiring; and
a ground layer inside the isolation insulating layer.

2. The semiconductor package of claim 1, wherein
the first printed wiring contacts a top surface and a side surface of the at least one first semiconductor chip, and
the second printed wiring contacts a top surface and a side surface of the at least one second semiconductor chip and contacts the isolation insulating layer on the at least one first semiconductor chip.

3. The semiconductor package of claim 1, wherein
the plurality of first chip pads include a first signal chip pad, a first ground chip pad, and a first power chip pad,
the plurality of second chip pads include a second signal chip pad, a second ground chip pad, and a second power chip pad, and
the second printed wiring connects the second signal chip pad to the second substrate pad.

4. The semiconductor package of claim 3, wherein
the first substrate pad includes a first signal substrate pad, a first ground substrate pad, and a first power substrate pad, and
the first printed wiring includes,
a signal wiring connecting the first signal chip pad to the first signal substrate pad,
a ground wiring connecting the first ground chip pad and the second ground chip pad to the first ground substrate pad, and
a power wiring connecting the first power chip pad and the second power chip pad to the first power substrate pad.

5. The semiconductor package of claim 4, wherein
the overlapping region includes a region from an exposed top surface of a topmost semiconductor chip of the at least one first semiconductor chip to the first ground substrate pad, and
the ground layer covers the overlapping region.

6. The semiconductor package of claim 4, wherein
the ground layer is connected to the ground wiring between the first ground chip pad of a topmost semiconductor chip of the at least one first semiconductor chip and the second ground chip pad of a bottommost semiconductor chip of the at least one second semiconductor chip.

7. The semiconductor package of claim 4, wherein
the isolation insulating layer includes a lower isolation insulating layer and an upper isolation insulating layer,
the lower isolation insulating layer covers the signal wiring in the overlapping region,
the ground layer covers the lower isolation insulating layer, and
the upper isolation insulating layer covers the ground layer.

8. The semiconductor package of claim 7, wherein
the lower isolation insulating layer has a line band shape, and the semiconductor package includes a plurality of lower isolation insulating layers corresponding to a plurality of signal wirings.

9. The semiconductor package of claim 7, wherein the lower isolation insulating layer has a sheet shape covering the overlapping region, and a single lower isolation insulating layer covers the signal wiring in the overlapping region.

10. The semiconductor package of claim 7, wherein
the upper isolation insulating layer has a line band shape or a sheet shape, and
the second printed wiring is on the upper isolation insulating layer in the overlapping region.

11. A semiconductor package comprising:
a package substrate including a first substrate pad and a second substrate pad;
at least one first semiconductor chip including a first signal chip pad and on the package substrate in a stepped structure;
at least one second semiconductor chip including a second signal chip pad and on the at least one first semiconductor chip in a stepped structure;
a first printed wiring connecting the first signal chip pad to the first substrate pad;
a second printed wiring connecting the second signal chip pad to the second substrate pad;
a lower isolation insulating layer covering the first printed wiring in an overlapping region in which the first printed wiring overlaps the second printed wiring;
a ground layer covering the lower isolation insulating layer; and
an upper isolation insulating layer covering the ground layer and having a portion of the second printed wiring on a top surface of the upper isolation insulating layer.

12. The semiconductor package of claim 11, wherein
the at least one first semiconductor chip further includes a first ground chip pad and a first power chip pad,
the at least one second semiconductor chip further includes a second ground chip pad and a second power chip pad, and
the first printed wiring,
connects the first ground chip pad and the second ground chip pad to the first substrate pad, and
connects the first power chip pad and the second power chip pad to the first substrate pad.

13. The semiconductor package of claim 12, wherein
the first substrate pad includes a first signal substrate pad, a first ground substrate pad, and a first power substrate pad, and
the first printed wiring includes,
a signal wiring connecting the first signal chip pad to the first signal substrate pad,
a ground wiring connecting the first ground chip pad and the second ground chip pad to the first ground substrate pad, and
a power wiring connecting the first power chip pad and the second power chip pad to the first power substrate pad.

14. The semiconductor package of claim 13, wherein
the overlapping region includes a region from an exposed top surface of a topmost semiconductor chip of the at least one first semiconductor chip to the first ground substrate pad, and
the ground layer covers the overlapping region and is connected to the ground wiring between the first ground chip pad of a topmost semiconductor chip of the at least one first semiconductor chip and the second ground chip pad of a bottommost semiconductor chip of the at least one second semiconductor chip.

15. The semiconductor package of claim 13, wherein
the lower isolation insulating layer has a line band shape, and the semiconductor package includes a plurality of lower isolation insulating layers corresponding to a plurality of signal wirings, or
has a sheet shape covering the overlapping region, and a single lower isolation insulating layer covers the first printed wiring in the overlapping region.

16. The semiconductor package of claim 13, further comprising:
a side insulating layer on a side surface of each of the at least one first semiconductor chip and the at least one first semiconductor chip,
wherein the first printed wiring and the second printed wiring extend on the side insulating layer.

17. A semiconductor package comprising:
a package substrate;
at least one first semiconductor chip of a first channel and on the package substrate in a stepped structure;
at least one second semiconductor chip of a second channel and on the at least one first semiconductor chip in a stepped structure;
a first printed wiring contacting a top surface and a side surface of the at least one first semiconductor chip, the first printed wiring providing signal connection of the first channel;
a second printed wiring contacting a top surface and a side surface of the at least one second semiconductor chip, the second printed wiring providing signal connection of the second channel; and
a multi-isolation layer including a ground layer therein and between the first printed wiring and the second printed wiring in an overlapping region in which the first printed wiring overlaps the second printed wiring.

18. The semiconductor package of claim 17, wherein the first printed wiring is connected to ground and to power connections of each of the first channel and the second channel.

19. The semiconductor package of claim 17, wherein
the package substrate includes,
a first substrate pad apart from the at least one first semiconductor chip, and
a second substrate pad farther apart from the at least one first semiconductor chip than the first substrate pad,
the first printed wiring is connected to the first substrate pad, and
the second printed wiring is connected to the second substrate pad.

20. The semiconductor package of claim 17, wherein
the multi-isolation layer includes,
a lower isolation insulating layer covering the first printed wiring in the overlapping region,
the ground layer covering the lower isolation insulating layer, and
an upper isolation insulating layer covering the ground layer, and
the second printed wiring is on a top surface of the upper isolation insulating layer in the overlapping region.
